(19) United States
(12) Patent Application Publication
(10) Pub. No.: US 2011/0187669 A1
(43) Pub. Date: Aug. 4, 2011

(54) LIQUID CRYSTAL DISPLAY DEVICE AND MANUFACTING METHOD THEREOF

(75) Inventors: Manabu Abiru, Osaka (JP); Makoto Ohue, Osaka (JP)

(73) Assignee: SHARP KABUSHIKI KAISHA, Osaka (JP)

(21) Appl. No.: 13/122,298

(22) PCT Filed: Jun. 24, 2009
(86) PCT No.: PCT/JP2009/002893

§ 371 Date: Apr. 1, 2011

(30) Foreign Application Priority Data
Nov. 12, 2008 (JP) 2008-290140

(51) Int. Cl. G06F 3/041; H01L 33/08

(52) U.S. Cl. 345/173; 438/30; 257/E33.053

(57) ABSTRACT

A protrusion for a touch sensor protruding toward the first substrate, an opposite electrode covering the protrusion for a touch sensor and the color filter layer, and a spacer defining the thickness of the liquid crystal layer are formed on a second substrate, and a touch electrode is formed on the first substrate and placed opposite the protrusion for a touch sensor through the opposite electrode therebetween. Furthermore, the spacer and the protrusion for a touch sensor are respectively formed in a single unit with the same material and with the same color as respective ones of the color layers of the color filter layer.

### TECHNICAL FIELD

The present invention relates to a liquid crystal display device which detects position information on the display screen and a method of manufacturing thereof.

### BACKGROUND ART

Liquid crystal display devices have been in wide use in recent years in personal computers, mobile phones, PDA, game consoles, and other types of systems. Furthermore, liquid crystal display devices, which detect the position information on the display screen, are also known and include a touch panel laid over a liquid crystal display panel. As the touch panel types, the resistive film type and the optical type are generally known.

In the resistive film type, a transparent conductive film is affixed on both the surface of a substrate, which is affixed on the display panel, and a surface on the substrate side of a film, which is affixed on the surface of this substrate with a minute gap. These transparent conductive films would come into contact at a position where a finger or a tip of a pen presses down, and a current would flow, enabling this position to be detected.

However, a configuration in which the touch panel is placed to overlap the display panel results in a reduction in the display contrast, because of the optical reflections at the surface of the display panel, at the back face of the touch panel, inside the touch panel, and at the surface of the touch panel.

Furthermore, the display quality may also suffer, resulting from a moiré caused by interference among the various reflected lights described above. Furthermore, the configuration in which the display panel and the touch panel are stacked results in a heavier and thicker display device unit.

As a result, liquid crystal display devices having a so-called in-cell type touch panel have been proposed with the liquid-crystal display panel and the resistive-film type touch panel making up a single unit. (See, for example, Patent Documents 1 through 3.)

Patent Document 1 discloses a first touch electrode placed to overlay a gate wiring line and a source wiring line on a TFT substrate making up a liquid crystal display panel, while a second touch electrode is placed to overlay a black matrix on an opposite substrate, so that the first and second touch electrodes form a lattice.

Patent Document 2 discloses a multi-gap type liquid crystal display device, in which each of the R, G, B color filter portions is formed on an opposite substrate with a different thickness, respectively. A spacer is formed in a region of the TFT substrate facing opposite the color filter portion for the color with the smallest cell thickness, while a protrusion for a touch sensor is formed with the same material as the spacer in the region of the TFT substrate which faces opposite the other color filter portions.

Patent Document 3 discloses a protrusion for a touch sensor formed on a color filter layer in which each of the R, G, and B color filter portions is formed with the same thickness as each other with the deposition of a plurality of color layers of the same material as the color filter portion.

### RELATED ART DOCUMENTS

### Patent Documents

Patent Document 1: Japanese Patent Application Laid-Open Publication No. 2001-075074
Patent Document 2: Japanese Patent Application Laid-Open Publication No. 2007-052369
Patent Document 3: Japanese Patent Application Laid-Open Publication No. 2006-119446

### SUMMARY OF THE INVENTION

### Problems to be Solved by the Invention

The liquid crystal display device having the aforementioned in-cell type touch panel, however, requires a sensor structure, such as a protrusion for a touch sensor for detecting the touch position, to be formed, and as a result, faces problems of a longer manufacturing process and higher manufacturing cost.

For example, the protrusion for a touch sensor and the spacer must be formed in a different process step from the color filter layer in Patent Documents 1 and 2, while the protrusion for a touch sensor must be formed in a separate process step from the spacer in Patent Document 3. Therefore, the manufacturing costs can be reduced by only so much.

The present invention has been made in consideration of these issues with the object of reducing the number of manufacturing steps and reducing the manufacturing cost of the liquid crystal display device having the liquid crystal display panel and the resistive-film type touch panel configured into a single unit.

### Means for Solving the Problems

In order to achieve the aforementioned objective, the present invention is directed at a liquid crystal display device including a first substrate on which a plurality of pixel electrodes are formed, a second substrate disposed to face opposite the first substrate and on which is formed a color filter layer including color layers of a plurality of colors, and a liquid crystal layer formed between the first substrate and second substrate. A protrusion for a touch sensor protruding on the side of the first substrate, an opposite electrode covering the protrusion for a touch sensor and the color filter layer, and a spacer defining the thickness of the liquid crystal layer are formed on the second substrate. A touch electrode is formed on the first substrate and placed opposite the protrusion for a touch sensor through the opposite electrode therebetween, coming in contact to and conducting electricity with the opposite electrode when the second substrate is pressed down and bows toward the first substrate. The spacer and the protrusion for a touch sensor are respectively formed in a single unit with the same material and with the same color as one of the color layers of the color filter layer.

It is preferred that a detection element be placed on the first substrate, be connected to the touch electrode, and detect an electrical conduction between the touch electrode and the opposite electrode.

A gate wiring line and a source wiring line extending orthogonally to the gate wiring line may be formed on the first substrate, and a detection wiring line, extending along the gate wiring line, and the source wiring line may be connected to the detection element.

The color filter layer may include color layers, respectively, of the red color, green color, and blue color, and the spacer may be formed in a single unit with the blue-colored color layer.

Furthermore, the present invention is directed at a method of manufacturing a liquid crystal display device having a first substrate, a second substrate disposed opposite to the first substrate through a liquid crystal layer therebetween and including a color filter layer made of color layers of a plurality of colors, a protrusion for a touch sensor formed on the second substrate and covered by an opposite electrode, and a touch electrode formed on the first substrate and disposed opposite to the protrusion for a touch sensor through the opposite electrode therebetween. The method of manufacturing a liquid crystal display device includes the step of forming the first substrate, the step of forming the second substrate, and the step of coupling the first substrate and the second substrate to each other and sealing a liquid crystal layer between the first substrate and second substrate. In the step for forming the second substrate, a spacer defining the thickness of the liquid crystal layer and the protrusion for a touch sensor, respectively, are formed into a single unit with the same material and with the same color as one of the color layers of the color filter layer.

It is preferred that a detection element connected to the touch electrode and detecting an electrical conduction between the touch electrode and the opposite electrode be formed on a substrate making up the first substrate in the step of forming the first substrate.

The color layers, the spacer, and the protrusion for a touch sensor may be exposed by exposure using a half-tone mask in the step of forming the second substrate.

The color filter layer may include color layers in each of the red color, green color, and blue color, and the spacer may be formed in a single unit with the blue-colored color layer in the step for forming the second substrate.

### Effects

The effects of the present invention are set forth next.

The aforementioned liquid crystal display device displays a desired image when a voltage is applied between a pixel electrode on the first substrate and an opposite electrode on the second substrate to drive the liquid crystal layer.

On the other hand, when the second substrate is pressed down and bows toward the first substrate, the opposite electrode covering the protrusion for a touch sensor, which is formed on the second substrate, comes into contact and conducts electricity with the touch electrode on the first substrate. Therefore, it is possible to detect the touch position on the second substrate based on the state of electrical conduction between the opposite electrode and the touch electrode.

Because the spacer and protrusion for a touch sensor are formed into a single unit with the same material and the same color with respect to one of the color layers in the color filter layer in the present invention, it is possible to form the spacer, protrusion for a touch sensor, and color filter layer simultaneously in the same steps. Therefore, it is possible to significantly reduce the number of manufacturing steps and achieve a large reduction in manufacturing cost.

Furthermore, by forming the detection element on the first substrate, it is possible to detect the state of electrical conduction between the touch electrode and the opposite electrode using the detection element.

Furthermore, it is possible to detect the signal detected by the detection element using the detection wiring line or the source wiring line by forming a detection wiring line extending along the gate wiring line on the first substrate and connecting the detection element to this detection wiring line and the source wiring line. In other words, the source wiring line may be used not only for the image display, but also for detecting the touch position.

Furthermore, the spacer that is thicker than the protrusion for a touch sensor may be formed into a single unit using the same material and the same color as the blue-colored color layer, when the color filter layer includes the color layers of each of the red color, green color, and blue color, so that it would be less visible to the user, compared with when it is formed with the colored layers of the red color and the green color, making it possible to maintain a good display quality.

### Effects of the Invention

According to the present invention, the spacer and the protrusion for a touch sensor are, respectively, formed into a single unit with the same material and the same color as one of the color layers of the color filter layer, and as a result, the spacer, the protrusion for a touch sensor, and the color filter layer can be formed simultaneously in the same steps. Consequently, the number of manufacturing steps is reduced, and the manufacturing cost is reduced significantly.

### BRIEF DESCRIPTION OF THE DRAWINGS

FIG. 1 is a cross-sectional drawing schematically showing a cross-sectional structure of a liquid crystal display device of the present embodiment.

FIG. 2 is a plan view drawing schematically showing a plurality of pixels in the liquid crystal display device of the present embodiment.

FIG. 3 is a plan view drawing showing a magnified view of a pixel on a TFT substrate.

FIG. 4 is a cross-sectional drawing along the line IV-IV of FIG. 3.

FIG. 5 is a circuit diagram showing a circuit configuration including a TFT and a detection element.

FIG. 6 is a cross-sectional drawing showing a half-tone exposure mask, disposed opposite a photosensitive material on a glass substrate.

FIG. 7 is a cross-sectional diagram showing color layers, protrusion for a touch sensor, and a spacer, formed by half-tone exposure.

### DETAILED DESCRIPTION OF EMBODIMENTS

Set forth in the descriptions below are the embodiments of the present invention in detail with reference to drawings. The present invention is not limited to these embodiments.

### Embodiments of the Invention

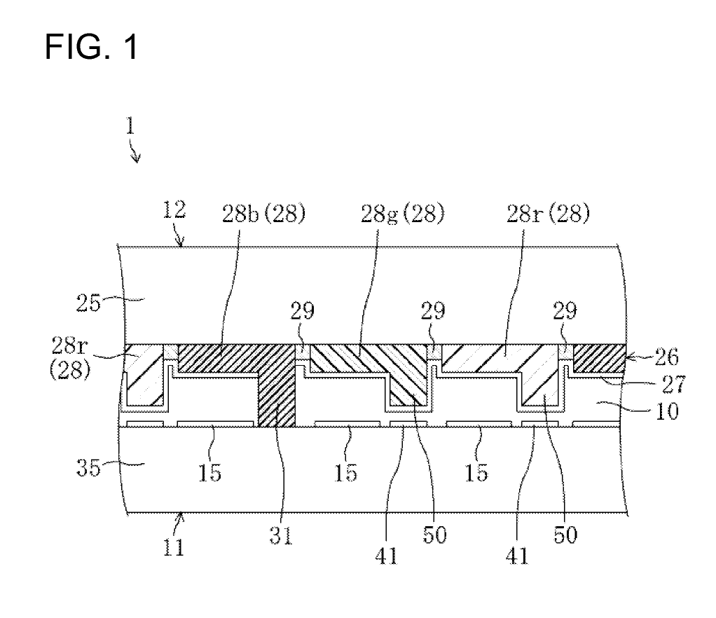

The embodiments of the present invention are shown in FIG. 1 through FIG. 7.

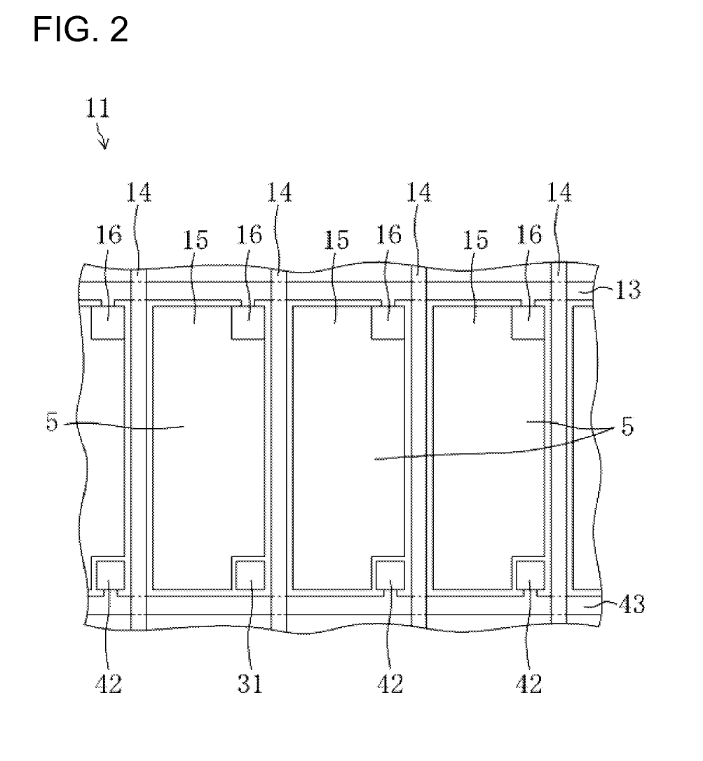

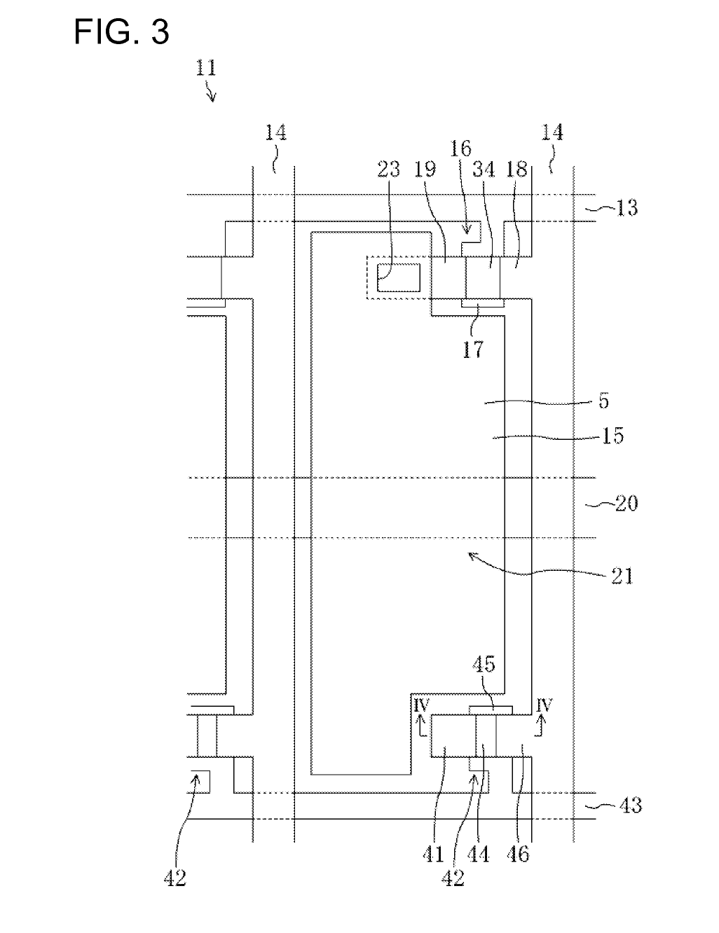

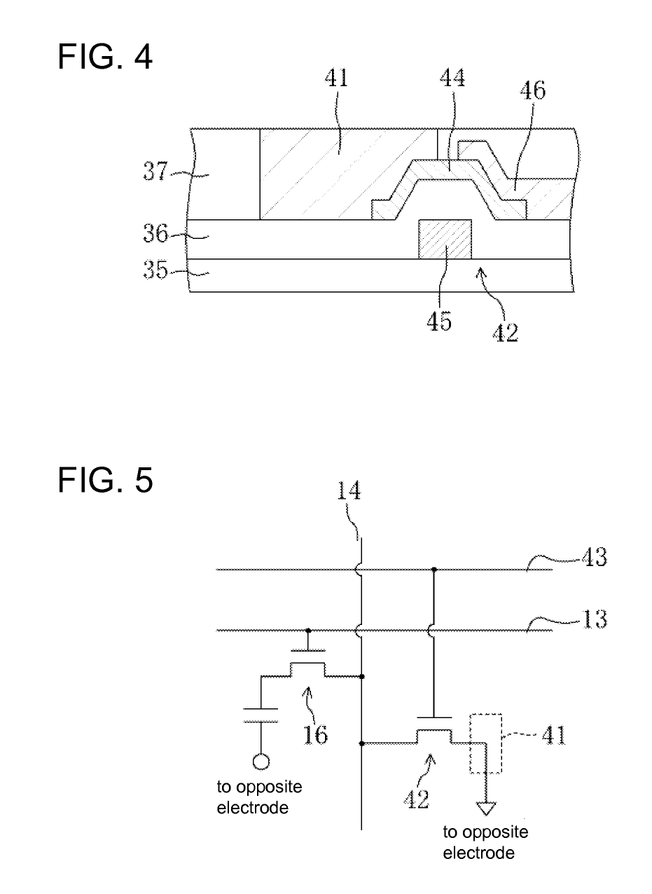

FIG. 1 is a cross-sectional drawing schematically showing the vertical cross-sectional structure of the liquid crystal display device 1 of the present embodiment. FIG. 2 is a plan view diagram schematically showing a plurality of pixels 5 of the liquid crystal display device 1 of the present embodiment. FIG. 3 is a plan view drawing showing an expanded view of a pixel 5 in the TFT substrate 11. FIG. 4 is a cross-sectional drawing along the line IV-IV of FIG. 3. FIG. 5 is a circuit diagram showing the circuit structure including the TFT 16 and detection element 42.

The liquid crystal display device 1 of the present embodiment is configured to be a transmissive liquid crystal display device offering at least a transmissive display. As shown in FIG. 1, the liquid crystal display device 1 includes a TFT substrate 11, which is a first substrate, an opposite substrate 12, which is a second substrate positioned to face the TFT substrate 11, and a liquid crystal layer 10, formed between the opposite substrate 12 and the TFT substrate 11.

Although not shown in the figure, the liquid crystal display device 1 includes, for example, a rectangular shaped display region and a frame region, which is a non-display region formed in the shape of a frame around this display region. The above-mentioned display region is made up of a plurality of pixels 5 laid out in a matrix.

As shown in FIG. 1, the opposite substrate 12 includes a glass substrate 25 of a thickness, for example, of 0.7 mm or less, a color filter layer 26, and an opposite electrode (common electrode) 27, which are stacked in this order on the side of the liquid crystal layer 10 on the glass substrate 25. The color filter layer 26 is made of the color layers 28 of a plurality of colors. The color layers 28 include a red-colored (R) color layer 28r, a green-colored (G) color layer 28g, and a blue-colored (B) color layer 28b. The color layers 28 of the various colors are laid out with the three colors, one next to the other. Furthermore, a black matrix 29, which is the light shielding film, is formed between the color layers 28 of various colors.

The opposite electrode 27 is made of, for example, ITO (indium tin oxide) and is formed essentially uniformly across the entire display region in such a way as to cover the color filter layer 26 and the black matrix 29. An alignment film, not shown in the figure, is formed on the surface on the side of the liquid crystal layer 10 of the opposite electrode 27. Furthermore, a polarizing plate, not shown in the figure, is pasted on the surface on the opposite side of the liquid crystal layer 10 of the glass substrate 25.

On the other hand, the TFT substrate 11 is configured to be a so-called active matrix substrate. The TFT substrate 11 includes a glass substrate 35 with a thickness of, for example, 0.7 mm or less, and, as shown in FIG. 2 and FIG. 3, a plurality of gate wiring lines 13 are formed in such a way as to extend in parallel with respect to each other. Furthermore, a plurality of source wiring lines 14 are formed in such a way as to extend orthogonally to the aforementioned gate wiring lines 13 on the TFT substrate 11. As a result, the wiring lines, made of the gate wiring lines 13 and the source wiring lines 14, are formed on the TFT substrate 11 in a lattice shaped pattern.

As shown in FIG. 2 and FIG. 3, each pixel 5 is made of a rectangular shaped region defined by the aforementioned gate wiring lines 13 and the source wiring lines 14. A plurality of pixel electrodes 15, which faces opposite the opposite electrodes 27, and a TFT (thin film transistor) 16, which is a switching device for switch-driving the liquid crystal layer 10 and is connected to the pixel electrode 15, are formed in each pixel 5.

The TFT 16 is placed, for example, in the upper right corner portion of the pixel 5 in FIG. 2 and FIG. 3 and includes a gate electrode 17 connected to the gate wiring line 13, a source electrode 18 connected to the source wiring line 14, and a drain electrode 19 connected to the pixel electrode 15. In other words, the gate wiring line 13 and the source wiring line 14 are connected to the TFT 16. Furthermore, a semiconductor layer 34 is interposed between the gate electrode 17 and the source electrode 18 and the drain electrode 19.

The drain electrode 19 is covered by an interlayer insulating film (not shown in the figure), and, as shown in FIG. 3, a contact hole 23 is opened through this interlayer insulating film. Furthermore, the drain electrode 19 is connected to the pixel electrode 15 through the contact hole 23. The pixel electrode 15 is covered by an alignment film not shown in the figure.

A signal voltage is supplied to the pixel electrode 15 from the source wiring line 14 through the source electrode 18 and the drain electrode 19 when the scanning voltage is applied on the gate electrode 17 through the gate wiring line 13. As a result, the liquid crystal layer 10 in this pixel 5 is driven by the signal voltage applied between the pixel electrode 15 and the opposite electrode 27, and a desired image is displayed.

Furthermore, a plurality of capacitance wiring lines 20 are formed on the TFT substrate 11 in parallel with each other and along the gate wiring lines 13 in such a way as to pass near the center of each of the pixels 5. An insulating film not shown in the figure is interposed between the capacitance wiring lines 20 and the pixel electrode 15, and a capacitance element 21, also called the auxiliary capacitance, is formed by these. The capacitance element 21 is formed in each pixel 5, respectively, and maintains the display voltage in each of the pixels 5 at essentially a constant level.

Furthermore, as shown in FIG. 1 through FIG. 4, a touch electrode 41 and a detection element 42, which is connected to the touch electrode 41, are formed respectively in each of the pixels 5 on the TFT substrate 11. The detection element 42 is for detecting an electrical conduction between the touch electrode 41 and the opposite electrode 27.

The detection element 42 is placed, for example, in the lower right corner portion of each of the pixels 5, as shown in FIG. 2 and FIG. 3, and is made of a TFT. As shown in FIG. 3 and FIG. 5, the detection wiring line 43, which extends along the gate wiring line 13, and the source wiring line 14, which has been mentioned above, are connected to the detection element 42.

In other words, the detection element 42 includes a gate portion 45, which is connected to the detection wiring line 43, a source portion 46, which is connected to the source wiring line 14, and a drain portion, which is the touch electrode 41. As shown in FIG. 4, a gate insulating film 36 is formed on the glass substrate 35 in such a way as to cover the gate portion 45. A semiconductor layer 44 is formed on the surface of the gate insulating film 36 in such a way as to cover the gate portion 45. Furthermore, the aforementioned source portion 46 and the touch electrode 41 are formed in such a way as to cover the surface of a part of the semiconductor layer 44. While the source portion 46 is covered by the interlayer insulating film 37, the touch electrode 41 is exposed and is not covered by the interlayer insulating film 37.

As shown in FIG. 3, in each pixel 5, the touch electrode 41 is placed in a missing portion of the pixel electrode 15 and is formed in such a way that its surface is at the same height as the pixel electrode 15 and is placed to face opposite the opposite electrode 27. Furthermore, the touch electrode 41 is made of, for example, ITO and is formed in the same step as the pixel electrode 15.

Furthermore, as shown in FIG. 1, a protrusion 50 for a touch sensor, which protrudes on the side of the TFT substrate 11, and a spacer 31, which defines the thickness of the liquid crystal layer 10, are formed on the opposite substrate 12. The protrusion 50 for a touch sensor as well as the color filter layer 26 are covered by the opposite electrode 27. The spacer 31 and the protrusion 50 for a touch sensor, respectively, are formed in a single unit with the same material and same color as one of the color layers 28 in the color filter layer 26.

In other words, the spacer 31 is formed in a single unit as the blue-colored color layer 28b and configured into a column shaped spacer. Furthermore, the spacer 31, as shown in FIG. 2, is placed, for example, in the lower right corner portion of the pixel 5, and its tip is in contact with the surface of the TFT substrate 11.

The protrusion 50 for a touch sensor is formed in a single unit with the green-colored color layer 28g or the red-colored color layer 28r, and the length of its protrusion is shorter than the spacer 31. These protrusions 50 for a touch sensors are placed, for example, in the lower right corner portions of the pixels 5 (in other words, in the vicinity of the detection elements 42), similar to the spacers 31.

On the other hand, the touch electrode 41, formed on the TFT substrate 11, is placed to face opposite the protrusion 50 for a touch sensor through the opposite electrode 27 therebetween. In other words, the touch electrode 41 faces opposite the opposite electrode 27 at the tip of the protrusion 50 for a touch sensor. As a result, the touch electrode 41 comes into contact and conducts electricity with the opposite electrode 27, when the opposite substrate 12 is pressed and bows toward the TFT substrate 11.

Touch Position Detection Method

Set forth next is a touch position detection method for the aforementioned liquid crystal display device 1.

When a prescribed scanning voltage is applied on the detection wiring line 43 of a certain row, the touch electrode 41 and the source portion 46 of the detection element 42, connected to this detection wiring line 43, become electrically conductive to achieve an ON state. If, at this time, the opposite substrate 12 is touched, and the opposite electrode 27 at the tip of the protrusion 50 for a touch sensor on the opposite substrate 12 comes into contact with the touch electrode 41 of the detection element 42, which is in the aforementioned ON state, a current flows through the source wiring line 14 in accordance with the voltage applied on the opposite electrode 27. When this current is detected, the touch position is detected.

On the other hand, if the opposite substrate 12 is not being touched, and the opposite electrode 27 is not in contact with the touch electrode 41 of the detection element 42, which is in the ON state, the current does not flow through the source wiring line 14. Therefore, the touch position is not detected in this instance, and a non-contact is detected. This sequence of position detection is then conducted one after next for respective rows, and the touch position detection is conducted for the entire display region.

Manufacturing Method

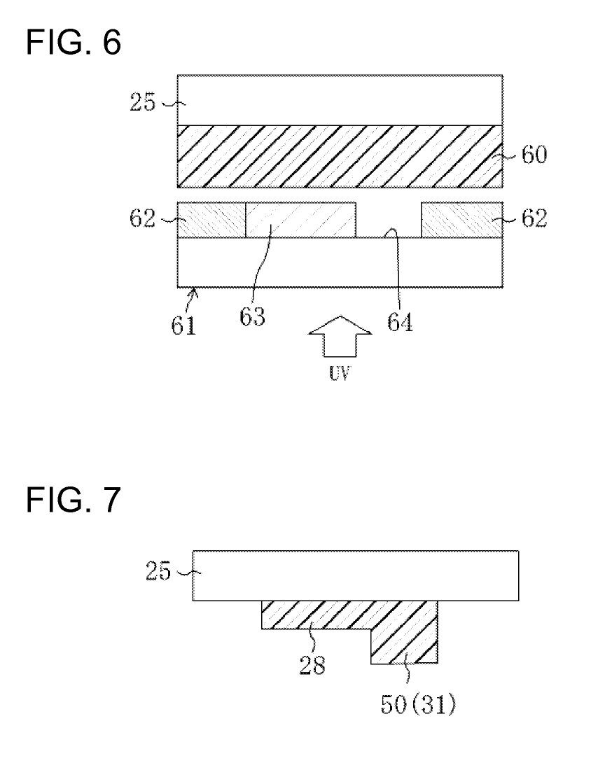

A method of manufacturing the aforementioned liquid crystal display device 1 is set forth next with reference to FIG. 6 and FIG. 7.

FIG. 6 is a cross-sectional drawing showing a mask 61 for half-tone exposure, which is placed to face opposite a photosensitive material on a glass substrate. FIG. 7 is a cross-sectional drawing showing the color layer 28 and either the protrusion 50 for a touch sensor or the spacer 31, which are formed by half-tone exposure.

First, the first process step for forming the TFT substrate 11 is conducted. In other words, the pixel electrode 15, TFT 16, and detection element 42, etc., are formed by photolithography on the glass substrate 35, which makes up the TFT substrate 11. The detection element 42 is formed simultaneously as the TFT 16 in the same process step.

On the other hand, the opposite substrate 12 is formed in the second process step. The first process step may take place first, or the second process step may take place first. In the second process step, the color filter layer 26 is formed on the glass substrate 25, which makes up the opposite substrate 12, and then an ITO film is deposited on the surface of this color filter layer 26 to form the opposite electrode 27.

Here in the second process step, the spacer 31 and the protrusion 50 for a touch sensor, respectively, are formed in a single unit with the same material and the same color as one of the color layers 28r, 28g, and 28b of the color filter layer 26.

As shown in FIG. 6, a photosensitive material 60, which is to become the color layer 28, is formed uniformly on the glass substrate 25, and then a half-tone exposure using the mask 61 is conducted on this photosensitive material 60. As a result, the color layer 28 and the protrusion 50 for a touch sensor, and the spacer 31 are formed simultaneously.

The mask 61 is a half-tone mask, on which a light shielding portion 62, which blocks the light (in other words, the transmissivity is 0%), a semitransmissive portion 63, which partially transmits light (for example, the transmissivity is 50%), and an opening portion 64 (in other words, the transmissivity is 100%) are formed. Then, ultraviolet light is irradiated on the photosensitive material 60 through the mask 61 to perform exposure. Then, as shown in FIG. 7, the protrusion 50 for a touch sensor or the spacer 31 is formed in a region which had faced opposite the opening portion 64, and at the same time the color layer 28 is formed in a region which had faced opposite the semitransmissive portion 63 by a develop process, for example.

The color filter layer 26 is formed on the glass substrate 25 by conducting this for each color. For example, the spacer 31 is formed in a single unit as the blue-colored color layer 28b, while the protrusion 50 for a touch sensor is formed in a single unit as either green-colored color layer 28g or red-colored color layer 28r.

Subsequently, the TFT substrate 11 and the opposite substrate 12 are affixed to each other, and the liquid crystal layer 10 is sealed between the TFT substrate 11 and the opposite substrate 12 in a third process step. The aforementioned liquid crystal display device 1 is thus manufactured.

### EFFECTS OF THE INVENTION

According to this embodiment, therefore, the spacer 31, protrusion 50 for a touch sensor, and color filter layer 26 can be formed simultaneously in the same process steps, because the spacers 31 and the protrusion 50 for a touch sensor, respectively, are formed in the single unit with the same material and same color as one of the color layers 28 of the color filter layer 26. As a result, it is possible to reduce the number of manufacturing process steps and significantly reduce the manufacturing costs.

Furthermore, the liquid crystal display device 1 as a whole has a thin form factor, and a plurality of touch positions can be detected simultaneously, in spite of the resistive film method, because the touch electrode 41, which comes into contact with the opposite electrode 27, and the detection element 42, which detects an electrical conduction between the aforementioned touch electrode 41 and the opposite electrode 27, when the opposite substrate 12 is pressed down, are placed in a plurality of pixels 5.

Furthermore, the number of wiring lines is reduced, and the aperture ratio of the pixel 5 is improved, because one of the detection wiring lines connected to the detection element 42 is also used as the source wiring line 14.

Furthermore, because the spacer 31, which has a larger thickness than the protrusion 50 for a touch sensor, is formed in a single unit with the same material and the same color as the blue-colored color layer 28b, it is less visible to the user, compared to when it is formed using the red-colored and green-colored color layers 28r and 28g. As a result, a high quality of display is maintained.

### Other Embodiments

In the aforementioned embodiments, one of the two wiring lines connected to the detection element 42 is described to be also used as the source wiring line 14 connected to the TFT 16 for the display control, as an example. The present invention, however, is not limited to this, and, in addition, one of the two wiring lines connected to the aforementioned detection element 42 may be the gate wiring line 13 in another configuration example. Furthermore, the two wiring lines connected to the aforementioned detection element 42 may be formed independently and separately from the source wiring line 14 and the gate wiring line 13. In such an instance, two detection wiring lines, extending along the source wiring line 14 and the gate wiring line 13, respectively, are formed. In this way, the detection accuracy can be further enhanced, because the touch locations can always be detected independently of the display control exerted by the gate wiring line 13 and the source wiring line 14.

Furthermore, while the spacer 31 was formed in a single unit with the blue-colored color layer 28b by the way of example in the above embodiment, the present invention is not limited to this, and it is possible to form a single unit with the other green-colored or red-colored color layers 28g or 28r.

Furthermore, the TFT 16 and the detection element 42 are not limited to be TFTs, and other switching elements, which turn on or off a flow of current, may also be used.

Furthermore, while the various aforementioned embodiments were described with the liquid crystal display device by the way of example, the present invention may also be applied on other display devices, including, for example, organic EL display devices.

### INDUSTRIAL APPLICABILITY

As set forth above, the present invention is useful for the liquid crystal display device which detects the location information on the display screen as well as the manufacturing method thereof.

### DESCRIPTION OF REFERENCE CHARACTERS

1 Liquid crystal display device
5 pixel
10 liquid crystal layer
11 TFT substrate (first substrate)
12 opposite substrate (second substrate)
13 gate wiring line
14 source wiring line
15 pixel electrode
25 glass substrate
26 color filter layer
27 opposite electrode
28 color layer
28r red-colored color layer
28g green-colored color layer
28b blue-colored color layer
31 spacer
41 touch electrode
42 detection element
43 detection wiring line
50 protrusion for a touch sensor
61 half-tone mask

1. A liquid crystal display device, comprising:
a first substrate on which a plurality of pixel electrodes are formed;
a second substrate disposed to face opposite said first substrate and having a color filter layer including color layers of a plurality of colors therein; and
a liquid crystal layer formed between said first substrate and said second substrate,
wherein a protrusion for a touch sensor protruding on the side of said first substrate, an opposite electrode covering said protrusion for a touch sensor and said color filter layer, and a spacer defining a thickness of said liquid crystal layer are formed on said second substrate,
wherein a touch electrode is formed on said first substrate and placed opposite said protrusion for a touch sensor through said opposite electrode therebetween, said touch electrode coming in contact with and electrically conducting with said opposite electrode when said second substrate is pressed down and bows toward said first substrate, and
wherein said spacer and said protrusion for a touch sensor are respectively formed in a single unit with the same material and with the same color respective ones of the color layers of said color filter layer.

2. The liquid crystal display device according to claim 1, wherein a detection element connected to said touch electrode to detect an electrical conduction between said touch electrode and said opposite electrode is placed on said first substrate.

3. The liquid crystal display device according to claim 2, wherein a gate wiring line and a source wiring line extending orthogonally to said gate wiring line are formed on said first substrate, and a detection wiring line, extending along said gate wiring line, and said source wiring line are connected to said detection element.

4. The liquid crystal display device according to claim 1 wherein said color filter layer includes color layers, respectively, of the red color, green color, and blue color, and said spacer is formed in a single unit with said blue-colored color layer.

5. A method of manufacturing a liquid crystal display device having a first substrate and a second substrate disposed opposite to said first substrate through a liquid crystal layer therebetween and including a color filter layer made of color layers of a plurality of colors, wherein a protrusion for a touch sensor covered by an opposite electrode is formed on said second substrate, and a touch electrode is formed on said first substrate and disposed oppositely to said protrusion for a touch sensor through said opposite electrode therebetween, the method comprising the steps of:
forming said first substrate;
forming said second substrate; and
coupling said first substrate and said second substrate to each other and sealing a liquid crystal layer between said first substrate and second substrate,
wherein, in the step of forming said second substrate, a spacer defining the thickness of said liquid crystal layer and said protrusion for a touch sensor are formed into a single unit with the same material and with the same color as respective ones of the color layers of said color filter layer.

6. The method of manufacturing the liquid crystal display device according to claim 5, wherein the step of forming said first substrate includes forming, on a substrate consisting said first substrate, a detection element connected to said touch electrode and detecting an electrical conduction between said touch electrode.

7. The method of manufacturing the liquid crystal display device according to claim 5, wherein the step of forming said second substrate includes forming said color layers, said spacer, and said protrusion for a touch sensor by exposure using a half-tone mask.

8. The method of manufacturing the liquid crystal display device according to claim 5, wherein said color filter layer includes color layers in each of the red color, green color, and blue color, and the step of forming said second substrate includes forming said spacer in a single unit with said blue-colored color layer.
